(19) United States
(12) Patent Application Publication
(10) Pub. No.: US 2007/0202648 A1
(43) Pub. Date: Aug. 30, 2007

(54) Memory device and method of manufacturing the same

(75) Inventors: Seong Jae Choi, Seoul (KR); Kwang Soo Seol, Suwon-si (KR); Jae-Young Choi, Suwon-si (KR); Dong-Kee Yi, Seoul (KR); Seon Mi Yoon, Yongin-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/652,583

(22) Filed: Jan. 12, 2007

(30) Foreign Application Priority Data
Feb. 28, 2006 (KR) 10-2006-0019302
Dec. 12, 2006 (KR) 10-2006-0126409

(51) Int. Cl. H01L 21/336

(52) U.S. Cl. 438/257; 257/E29.3

(57) ABSTRACT

Provided is a memory device comprising a substrate, a source region, and a drain region that may be formed in the substrate and spaced apart from each other, a memory cell that may be formed on the surface of the substrate, connecting the source region and the drain region, and including a plurality of nanocrystals, wherein the memory cell comprises a first tunneling oxide layer formed on the substrate, and a control oxide layer including a plurality of nanocrystals formed on the tunneling oxide layer and a control gate formed on the memory cell. The memory device may include a polyelectrolyte film which enables a uniform arrangement of nanocrystals. The device characteristics may be controlled and a memory device with improved device characteristics may be provided.

### PRIORITY STATEMENT

This application claims priority under 35 U.S.C. §119 to Korean Patent Application No. 10-2006-0019302, filed on Feb. 28, 2006 and Korean Patent Application No. 10-2006-0126409, filed on Dec. 12, 2006, in the Korean Intellectual Property Office (KIPO), the entire contents of which are incorporated herein by reference.

### BACKGROUND

1. Field

Example embodiments relate to a memory device including nanocrystals and methods of manufacturing and operating the memory device. Other example embodiments relate to a memory device including a polyelectrolyte film and nanocrystals and methods of manufacturing and operating the memory device.

2. Description of the Related Art

A memory device using a semiconductor may include, as basic elements, a transistor that functions as a switch to provide a path for a current when recording or reading information whereby the transistor may be placed in a capacitor, and a capacitor that preserves stored charges. A transistor may have a relatively high transconductance in order for an improved amount of current to flow. Conventionally, a metal oxide semiconductor field effect transistor (MOSFET) having a relatively high transconductance may often be used as a switching device of a semiconductor memory device. A MOSFET may include, as basic elements, a gate electrode formed of multi-crystalline silicon, and source and drain electrodes formed of doped crystalline silicon.

As information equipment develops, research on reducing the size of memory devices is being conducted in order to obtain relatively highly integrated memory devices, thereby increasing the number of integrated memory devices per unit surface area. When such highly integrated memory devices are used, the signal transmission time between devices may be reduced and thus an improved amount of information may be processed at a relatively high speed. In a conventional MOSFET, the amount of heat generated in the MOSFET may be improved, and thus when the integration of the memory device increases, the device may melt or function undesirably. A single electron device (SED) has been developed to solve such problems. Ann SED may use electrical signals by transmitting one electron. It may be necessary to develop a device to precisely control the transmission of the electron. One material satisfying this requirement may be nanocrystals. A nanocrystal may be a material composed of a metal and/or semiconductor, having a smaller size than a Bohr exciton radius, for example, about a few nanometers. There may be a greater amount of electrons in the nanocrystals, but the number of free electrons in the nanocrystals may be limited to the range of about 1 to about 100.

The energy potential of the electrons of the nanocrystals may be discontinuously limited and thus the nanocrystals may show different electrical and optical properties from the nanocrystals composed of a metal and/or semiconductor that may be in a bulk state, which forms a continuous band. Conventionally, various conductors and nonconductors may have to be mixed in order to obtain a predetermined or given band gap. Nanocrystals may have different energy potentials which vary according to the size of the nanocrystals, and thus the band gap may be controlled by changing the size.

Also, unlike a bulk type semiconductor, the amount of energy required to add electrons may not be uniform but may change stepwise according to the addition of each electron. A Coulomb blockade effect, in which a previously present electron disturbs the addition of a new electron, may occur. When there are a predetermined or given number of electrons needed for crystals, an additional transfer of electrons by tunneling may be blocked. When the size of the nanocrystals is less than about 10 nm theoretically, a single electron may be transferred. Because the number of transferred electrons is smaller, the amount of generated heat accompanying the transferred electrons may also be relatively small, and this may enable a reduction in the size of the device.

The nanocrystals may be used in a relatively small device when combined with a transistor. Research into a memory device using nanocrystals may be conducted. Conventional nanocrystals used in memory devices may be manufactured by a heat treatment. Nanocrystals having a relatively high melting point may not be treated with heat. Even though the nanocrystals are manufactured by heat treatment, the size of the nanocrystals may not be uniform, which may deteriorate the device characteristic of the manufactured memory device.

### SUMMARY

Example embodiments provide a method of manufacturing a memory device using polyelectrolytes. Other example embodiments provide a memory device including a tunneling oxide layer. Other example embodiments provide a method of operating a memory device.

According to example embodiments, a method of manufacturing a memory device may include providing a substrate, forming at least one tunneling oxide layer on a surface of the substrate, forming a polyelectrolyte layer on a surface of the at least one tunneling oxide layer, arranging nanocrystals on the polyelectrolyte layer and forming a control oxide layer on the surface of the at least one tunneling oxide layer in which the nanocrystals may be arranged.

According to example embodiments, the at least one tunneling oxide layer may include first and second tunneling oxide layers. The method may further include forming a source and drain region on the surface of the substrate and forming a control gate on the surface of the control oxide layer. According to example embodiments, the polyelectrolyte forming the polyelectrolyte layer may include at least one polymer selected from the group consisting of polyallylamine hydrochloride, polydiallyldimethylammonium chloride, polyacrylic acid, poly sodium-4-styrene-sulfonate, polyethyleneimine and/or polyvinyl pyridine. The material forming the tunneling oxide layer may be silicon oxide, silicon nitride, lanthanum oxide, lanthanum silicate and/or lanthanum aluminate.

According to other example embodiments, the material forming the tunneling oxide layer may be SiO₂, SiOₓN_{y}, ZrO₂, HfONₓ, ZrONₓ, TiO₂, Ta₂O₅, La₂O₃, PrO₂, HfSiO₂, ZrSiO₂ and/or HfSiOₓN_{y}. The nanocrystals may be arranged on the polyelectrolyte layer using a method (e.g., spin-coating, dip coating and/or drop casting). The nanocrystals may be capped with polar organic molecules having charges. The nanocrystals may be metal nano particles including Pt, Pd, Co, Cu, Mo, Ni, Fe; Group II-VI compound semiconductor nano particles including CdS, CdSe, CdTe, ZnS, ZnSe, ZnTe, HgS, HgSe, HgTe; Group III-V compound semiconductor nano particles including GaN, GaP, GaAs, InP, InAs; or PbS, PbSe, and PbTe, wherein the nanocrystals may be a metal or alloy having a size of about 10 nm or less or may be in a Core-Shell structure. The nanocrystals may be arranged as a monolayer.

According to example embodiments, a memory device may include a substrate, a source region and a drain region that may be formed in the substrate and may be spaced apart from each other, a memory cell that may be formed on the surface of the substrate, connecting the source region and the drain region, and including a plurality of nanocrystals, wherein the memory cell may include a tunneling oxide layer formed on the substrate; and a control oxide layer including a plurality of nanocrystals formed on the tunneling oxide layer, and a control gate formed on the memory cell.

According to example embodiments, the at least one tunneling oxide layer may include first and second tunneling oxide layers. The material forming the tunneling oxide layer may be silicon oxide, silicon nitride, lanthanum oxide, lanthanum silicate and/or lanthanum aluminate. The material forming the tunneling oxide layer may be SiO₂, SiOₓN_{y}, ZrO₂, HfONₓ, ZrONₓ, TiO₂, Ta₂O₅, La₂O₃, PrO₂, HfSiO₂, ZrSiO₂ and/or HfSiOₓN_{y}. The memory device may further include one kind of nanocrystals selected from the group consisting of metal nano particles including Pt, Pd, Co, Cu, Mo, Ni, Fe; Group II-VI compound semiconductor nano particles including CdS, CdSe, CdTe, ZnS, ZnSe, ZnTe, HgS, HgSe, HgTe; Group III-V group compound semiconductor nano particles including GaN, GaP, GaAs, InP, InAs and PbS, PbSe, and PbTe, wherein the nanocrystals may be a metal and/or alloy having a size of about 10 nm or less or may be in a Core-Shell structure. In the memory device, a plurality of nanocrystals included in the control oxide layer may be arranged as a monolayer.

According to example embodiments, a method of operating a memory device may include grounding a source region, and applying a voltage (Vd>0) to a drain region so that electrons move from the source region to the drain region, and wherein when a gate voltage Va is greater than a drain voltage Vd, electrons move to a memory cell. The gate voltage may be a write voltage (Va=0). The method may further include applying a read voltage smaller that the gate voltage Va during writing to the drain region, wherein the gate voltage is about 0. The method may also further include applying an erase voltage to the source region to allow electrons to move to the source region, wherein the gate voltage is about 0 and the erase voltage is greater than 0.

### BRIEF DESCRIPTION OF THE DRAWINGS

Example embodiments will be more clearly understood from the following detailed description taken in conjunction with the accompanying drawings. FIGS. 1-7 represent non-limiting, example embodiments as described herein.

FIG. 1 is a diagram of a memory device according to example embodiments;

FIGS. 2A-2E illustrate a method of manufacturing a memory device according to example embodiments;

FIGS. 3A-3F illustrate a method of manufacturing a memory device according to example embodiments;

FIG. 4 is a scanning electrographic microscope (SEM) photograph showing nanocrystals arranged on a surface of a second tunneling oxide layer in Example 1;

FIG. 5 is an SEM photograph showing nanocrystals arranged on a surface of a second tunneling oxide layer in Example 2;

FIG. 6 is a graph illustrating the variation of a flat band voltage VFB according to programming time and erasing time of the memory device of Example 1; and

FIG. 7 is a graph of the predicted data storing time period of the memory device of Example 1.

### DETAILED DESCRIPTION OF EXAMPLE EMBODIMENTS

Hereinafter, a method of manufacturing a memory device according to example embodiments will be explained in detail with reference to the accompanying drawings. In the drawings, the thicknesses and shapes of layers are exaggerated for description of exemplary embodiments. Like reference numbers refer to like elements throughout the specification.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below.” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unlike a conventional method of manufacturing a memory device, the characteristics of which may be more difficult to control due to the size and irregular arrangement of nanocrystals, in a method of manufacturing a memory device according to example embodiments, nanocrystals synthesized to a uniform size in a colloid state may be arranged as a monolayer, and thus the characteristics of the device may be controlled, and a memory device with improved device characteristics may be provided.

Example embodiments provide a method of manufacturing a memory device which may include providing a substrate, forming a tunneling oxide layer on a surface of the substrate, forming a polyelectrolyte layer on a surface of the tunneling oxide layer, arranging nanocrystals on the polyelectrolyte layer as a monolayer, and forming a control oxide layer on the surface of the tunneling oxide layer in which the nanocrystals may be arranged.

The method of manufacturing a memory device may further include forming source and drain regions on the surface of the substrate and forming a control gate on the surface of the control oxide layer. The source region and the drain region may be formed in any state after a substrate is provided and may not depend on the order of operations. Examples of the polyelectrolyte forming the polyelectrolyte layer may include polyallylamine hydrochloride, polydiallyidimethylammonium chloride, polyacrylic acid, poly sodium-4-styrene-sulfonate, polyethyleneimine and/or polyvinyl pyridine.

The polyelectrolyte layer including the polymer may function as a temporary supporting layer which provides electrostatic attraction that enables the nanocrystals to be arranged as a monolayer. The polyelectrolyte layer may function as a kind of supporter and may provide electrostatic attraction so that nanocrystals may be arranged as a monolayer. For example, ammonium ions of polydiallyldimethylammonium chloride formed on the surface of the tunneling oxide layer and acetate ions of mercaptoacetic acid capped on the surface of the nanocrystals may be combined by electrostatic attraction, and thus the nanocrystals may be formed as a monolayer on the surface of the polyelectrolyte layer.

Examples of the material forming the tunneling oxide layer in the memory device may include silicon oxide and/or nitride, and/or metal oxide of lanthanoid (lanthanum oxide) and/or silicate (lanthanum silicate) and/or an aluminate (lanthanum aluminate) thereof, for example, SiO₂, SiOₓN_{y}, ZrO₂, HfONₓ, ZrONₓ, TiO₂, Ta₂O₅, La₂O₃, PrO₂, HfSiO₂, ZrSiO₂ and/or HfSiOₓN_{y}, but may be not limited thereto. Any material that may be used in the technical field may be used. The nanocrystals may be arranged on the polyelectrolyte layer using a wet method (e.g., spin-coating, dip coating and/or drop casting) but may be not limited thereto. Any wet method, which may form the relatively large monolayer of nanocrystals, may be used.

The nanocrystals may be capped by polar organic molecules. When the nanocrystals are synthesized as a colloid, organic molecules having a predetermined or given substitution group may be coordinated to cap the surface of nanocrystals. Various kinds of organic molecules may be used for capping, but in general, one molecule may include two functional groups. One of the functional groups may be bonded to the nanocrystals, and the other functional group at the other end may be polar, thereby increasing dispersibility to the polar solvents. The nanocrystals having polarity may be maintained in a dispersed state and prevent or reduce condensation between nanocrystals.

Examples of one of the functional groups that are bonded with the nanocrystals may be phosphine oxide, phosphonic acid, carboxylic acid, amine, thiol, and so forth, and the functional group on the other end of the organic molecules may be any functional group having polarity, having positive and/or negative charges. A functional group having polarity positioned within a molecule (e.g., polyethylene glycol group) may also be used.

The nanocrystals may be selected from the group consisting of metal nano particles including Pt, Pd, Co, Cu, Mo, Ni, Fe; Group II-VI compound semiconductor nano particles including CdS, CdSe, CdTe, ZnS, ZnSe, ZnTe, HgS, HgSe, HgTe; Group III-V compound semiconductor nano particles including GaN, GaP, GaAs, InP, InAs; and PbS, PbSe, and PbTe, wherein the nanocrystals may be a metal and/or alloy having a size of about 10 nm or less or may be in a Core-Shell structure.

In the method of manufacturing a memory device, the nanocrystals may be arranged as a monolayer. Also, the interval between the nanocrystals may be uniform. As the nanocrystals are arranged as a monolayer, the voltage needed for the electrons to be transferred to the nanocrystals may be reduced, and the time required for electron transfer may also be reduced and consequently relatively high integration of the memory device may become possible.

Also, example embodiments provide a memory device, prepared according to the above mentioned method, including a substrate, a source region and a drain region that may be formed in the substrate and spaced apart from each other, a memory cell that may be formed on the surface of the substrate, which connects the source region and the drain region, and may include a plurality of nanocrystals, a control gate formed on the memory cell. The memory cell may include a tunneling oxide layer formed on the substrate and a control oxide layer including a plurality of nanocrystals formed on the tunneling oxide layer.

The memory device of example embodiments may be manufactured by forming a polyelectrolyte film on the surface of the tunneling oxide layer using a wet method, and then arranging uniform nanocrystals according to a desired size as a monolayer by using electrostatic force. The kind and size of the nanocrystals may be controlled compared to the method of manufacturing a memory device using sputtering. For example, when Pd nanocrystals capped with oleylamine are directly spin-coated on the surface of the tunneling oxide layer (HfO₂), nanocrystals may be condensed, which may make it more difficult to achieve a monolayer arrangement.

Examples of the material forming the tunneling oxide layer may include silicon oxide and/or nitiride and/or metal oxide of lanthanoid of silicate and/or an aluminate thereof, for example, SiO₂, SiOₓN_{y}, ZrO₂, HfONₓ, ZrONₓ, TiO₂, Ta₂O₅, La₂O₃, PrO₂, HfSiO₂, ZrSiO₂ and/or HfSiOₓN_{y}, but may not be limited thereto, and any material that may be used in the technical field may be used. The nanocrystals may be at least one selected from the group consisting of metal nano particles including Pt, Pd, Co, Cu, Mo, Ni, Fe; Group II-VI compound semiconductor nano particles including CdS, CdSe, CdTe, ZnS, ZnSe, ZnTe, HgS, HgSe, HgTe; Group Ill-V compound semiconductor nano particles including GaN, GaP, GaAs, InP, InAs; and PbS, PbSe, and PbTe, wherein the nanocrystals may be a metal and/or alloy having a size of about 10 nm or less or may be in a Core-Shell structure.

In the memory device, a plurality of nanocrystals included the control oxide layer may be arranged as a monolayer. The arrangement of the monolayer may improve the device characteristics of the memory device. The nanocrystals may be arranged at a uniform interval. The nanocrystals in the colloid state manufactured using a wet synthesizing method may be easier to manufacture and a wet coating method may be applied thereto. Also, the kind of elements forming the nanocrystals may not be limited, and the adjustment of the size of the nanocrystals and the selection of capping molecules may be straightforward, thereby obtaining nanocrystals having a more uniform size. Also, because the nanocrystals may be charged electrostatically, the nanocrystals may not lump together but may be arranged at uniform intervals when coated on a predetermined or given substrate, and may be arranged as a monolayer. A memory device including nanocrystals and a method of manufacturing the memory device according to example embodiments will now be described more fully with reference to the accompanying drawings, in which example embodiments may be shown.

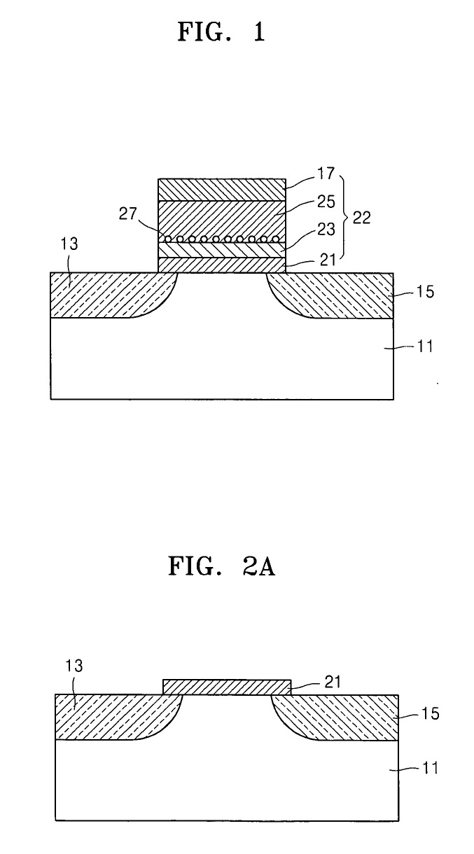

FIG. 1 is a diagram of a memory device including nanocrystals according to example embodiments. Referring to FIG. 1, the memory device including nanocrystals according to example embodiments may include a substrate 11, a source region 13 and a drain region 15 spaced apart by a predetermined or given distance and having a predetermined or given depth from the surface, a memory cell 22 that may be formed on the surface of the substrate 11, connecting the source region 13 and the drain region 15 and including a plurality of nanocrystals, and a control gate 17 formed on the memory cell 22.

The control gate 17 may control the number of electrons stored in the memory cell 22. The substrate 11 may be a semiconductor substrate formed of silicon. The source region 13 and the drain region 15 may be formed as an n-type and/or a p-type by a conventional semiconductor process, for example, a diffusion process after a doping process. The memory cell 22 may include a first tunneling oxide layer 21 through which electrons formed in the substrate 11 may pass, a second tunneling oxide layer 23 through which electrons, formed in the first tunneling oxide layer 21, may pass and a control oxide layer 25, including a plurality of nanocrystals 27, formed on the second tunneling oxide layer 23.

When the source region 13 is grounded and a predetermined or given voltage (Vd>0) is applied to the drain region 15, electrons may move from the source region 13 to the drain region 15, and during this process, when a gate voltage Va is greater than a drain voltage Vd, electrons may move to the memory cell 22. The number of the electrons may be determined by the thickness and material of the first and second tunneling oxide layers 21 and 23, and the number of tunneling electrons may be decided by the size and the inner material of the nanocrystals 27. Once electrons enter the nanocrystals 27, the other electrons may be blocked by the above described Coulomb blockage, for example, Coulomb repulsion. When the gate voltage Va is increased to an appropriate voltage, the Coulomb repulsion may be overcome and more electrons may flow into the nanocrystals 27.

A writing operation will now be described. In the above described condition, when the gate voltage Va is 0, tunneling may not occur and an electron storing material and electrons in the nanocrystals 27 may combine, thereby recording information. Data “1” may be where an improved amount of electrons are stored, and data “0” may be where fewer electrons are stored, by properly adjusting the gate voltage Va. A reading operation will now be described. When a voltage smaller than the gate voltage Va is applied, during writing, to the drain region 15 and a gate voltage V is about 0, then it may be determined whether current of a memory cell flows or not, according to the threshold voltage of the memory cell, and 1 or 0 may be read by measuring the drain voltage Vd.

An erasing operation will now be described. When the gate voltage Va is about 0, and a relatively high voltage is applied to the source region 13, and the drain region 15 is opened, electrons may move to the source region 13, thereby erasing the information of the memory cell 22. Described above may be reading, writing, and erasing operations when the memory device, according to example embodiments, operates as a read only memory (ROM).

If the memory device of example embodiments is used as random access memory (RAM), the memory cell 22 may operate in the same manner as a capacitor. A smaller amount of charge may be stored in the nanocrystals, and these charges may be more easily lost by a smaller amount of leakage current, thus requiring recording again. If the source region 13 is grounded, and a predetermined or given voltage is applied to the drain region 15, electrons may move from the source region 13 to the drain region 15. If the gate voltage Va is higher than the drain voltage Vd, electrons may tunnel to the memory cell 22 and may be stored in the nanocrystals, thereby recording information. The above principle may also be applicable to a memory device used as a ROM as described above, but RAM may be different from the ROM in that the electrons in the RAM may be removed if power is no longer supplied. This is because a RAM may store electrons for only a relatively short amount of time.

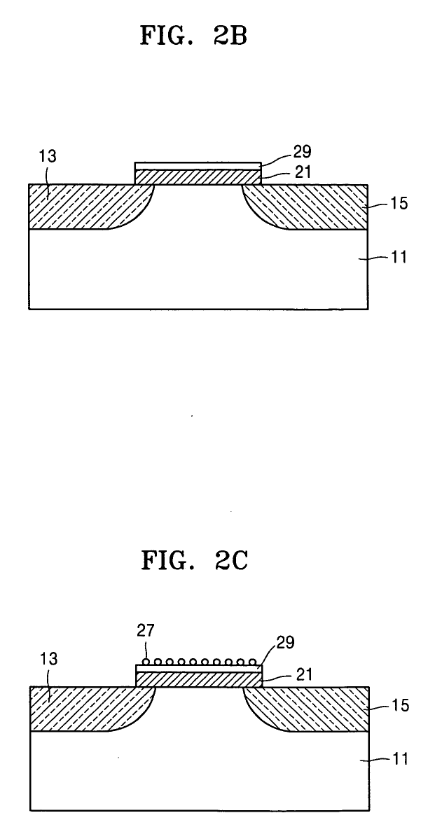

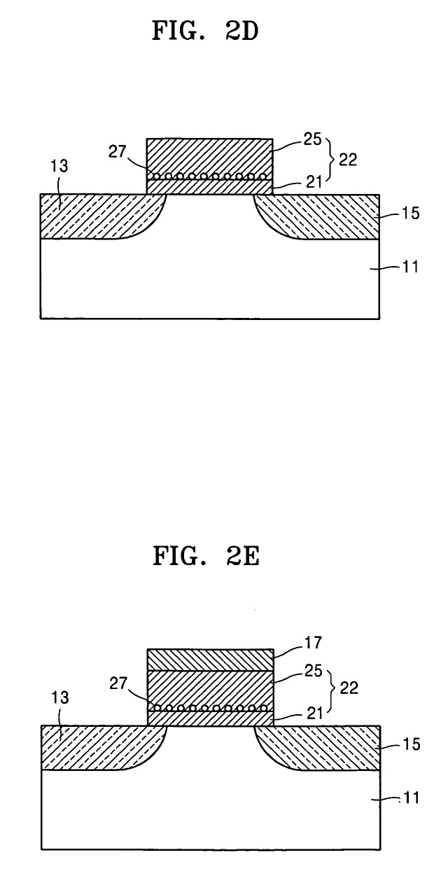

FIGS. 2A-2E illustrate a method of manufacturing a memory device including a different type of nanocrystals according to example embodiments. As illustrated in FIGS. 2A-2E, a silicon substrate 11 is provided, and a source region 13 and a drain region 15 which may be spaced apart by a predetermined or given distance in the substrate 11 may be formed using ordinary semiconductor processes (e.g., ion injection and/or a diffusion process) and a tunneling oxide layer 21, for example, a multiple layer formed of silicon oxide/ hafnium oxide, may be formed. The tunneling oxide layer 21 may be deposited using an atomic layer deposition (ALD) method.

A polyelectrolyte layer 29 may be formed on the surface of the tunneling oxide layer 21. The polyelectrolyte layer may be formed using a wet method (e.g., spin-coating). A nanocrystal solution in the form of a colloid having an opposite charge to the polyelectrolyte may be coated on the surface of the polyelectrolyte layer using a wet method (e.g., spin-coating) to form a monolayer of nanocrystals that may be arranged by electrostatic attraction. A control oxide layer, for example, a hafnium oxide layer, may be formed on the surface of the tunneling oxide layer in which the nanocrystals may be arranged. A control gate 17 may be formed on the control oxide layer, and thus a memory device according to example embodiments may be completed.

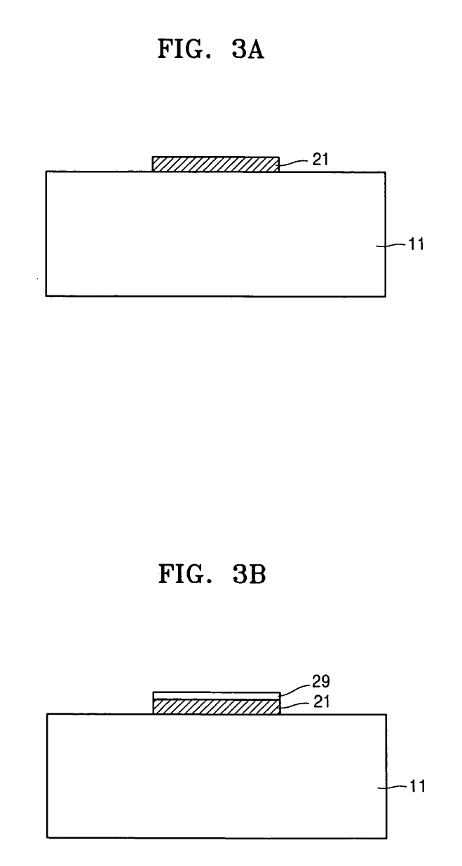

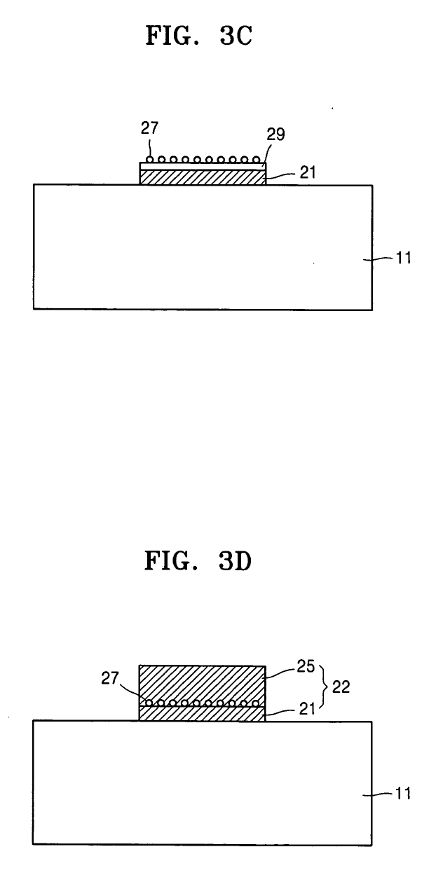

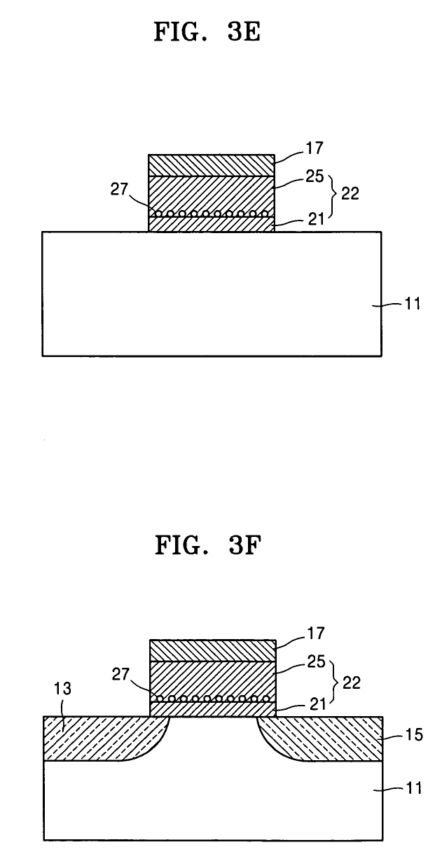

The source region 13 and the drain region 15 may be formed first as described above, but as illustrated in FIGS. 3A-3F, the source region 13 and the drain region 15 may be formed last using semiconductor processes (e.g., ion injection and/or diffusion), after the control gate 17 may be formed.

Hereinafter, example embodiments will be described in more detail with reference to the following examples. However, these examples may be for illustrative purposes only and may not be intended to limit the scope of example embodiments.

### Manufacture of Memory Device

### EXAMPLE 1

A silicon substrate may be provided. A silicon oxide (SiO₂) layer having a thickness of about 2 nm, which is a third tunneling oxide, may be formed using a thermal oxidization. A tunneling oxide layer may be formed by stacking a hafnium oxide (HfO₂) layer to a thickness of about 5 nm, which is a first tunneling oxide, using an atomic layer deposition (ALD) method. The temperature during formation of the silicon oxide layer may be about 1000° C., and O₂ may be used as reaction gas. The deposition temperature during formation of a hafnium layer is about 200° C. or about 350° C., and tetrakisethylmethylamide (Hf-TEMA) may be used as the hafnium source gas, and O₂ and/or H₂O may be used as reaction gas.

The deposition of HfO₂ layer using the ALD method was performed as follows. A source gas flow operation, a purge operation, a reaction gas flow operation, and a purge operation were performed sequentially, and this deposition cycle was repeated until a layer with a desired thickness was obtained. The surface of the HfO₂ layer was spin-coated, using about 10 mM of poly(allylamine hydrochloride) solution dispersed in water, at about 5000 rpm to form a polyelectrolyte film having a thickness of about 1 nm.

Negatively charged Pd nanocrystals dispersed in a pH 8 buffer solution were spin-coated on the surface of the polymer electrolyte film at about 3000 rpm to form a nanocrystal monolayer. The Pd nanocrystals used herein were Pd nanocrystals with a diameter of about 5 nm, capped with mercaptoacetic acid. The hafnium oxide layer was deposited to a thickness of about 30 nm. The deposition conditions were the same as described above. Finally, the control gate was deposited, and impurities were injected to form a source region and a drain region to complete a memory device.

### EXAMPLE 2

A memory device was manufactured in the same manner as Example 1 except that about 10 mM of poly(ethyleneimine) solution was spin-coated to a thickness of about 1 nm at about 5000 rpm instead of poly(allylamine hydrochloride) solution.

### Evaluation of Arrangement of Nanocrystals

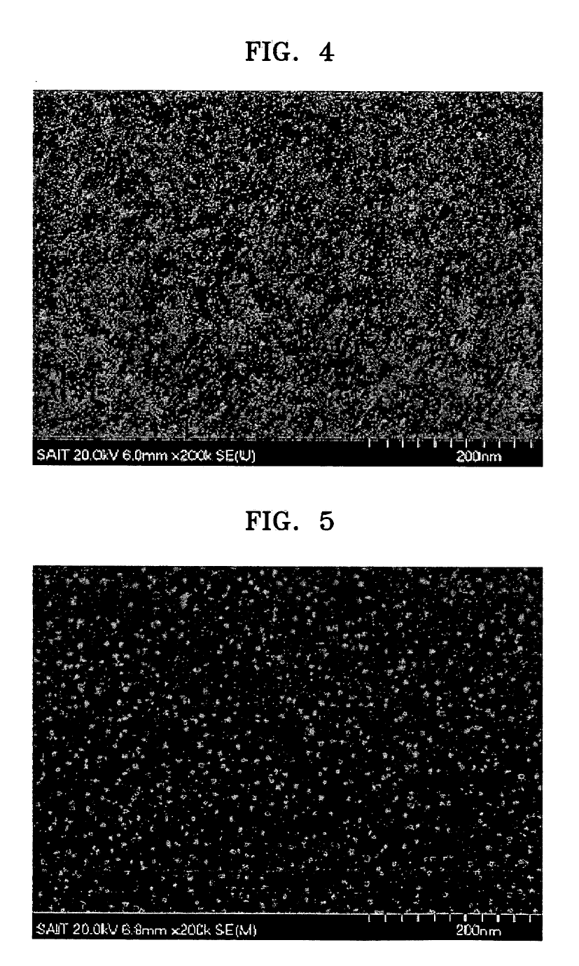

The nanocrystals were arranged during the manufacture of the memory device in Examples 1 and 2, and then the arrangement of the nanocrystals was measured using a scanning electron microscope (SEM) and the result showing the arranged nanocrystals may be illustrated in FIGS. 4 and 5. The result shows that the nanocrystals in Examples 1 and 2 were arranged as a monolayer relatively uniformly and without agglomeration.

### Evaluation of the Characteristics of Memory Device

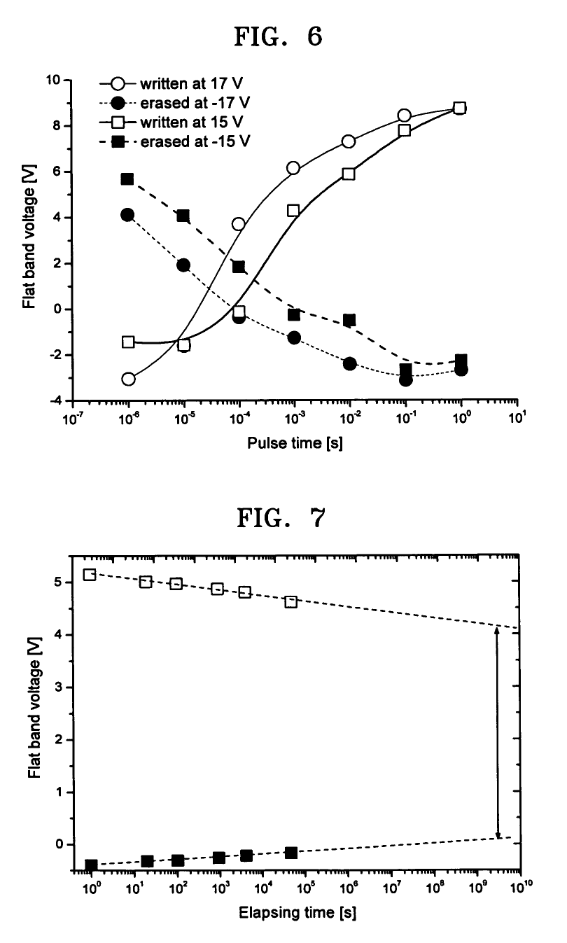

The program characteristics and retention characteristics of the memory device manufactured according to Example 1 were measured. FIG. 6 is a graph illustrating the variation of a flat band voltage VFB according to the programming time and erasing time of a memory device of Example 1. Programming voltages of about 17V and about 15V and erasing voltages of about −17V and about −15V were applied to measure the programming time and erasing time of the memory device.

As illustrated in FIG. 6, the memory device of Example 1 may obtain a memory window of about 6V in the range of about 300 μs (writing) to about −10 msec (erasing) which is sufficient for programming and erasing. Data may be sufficiently programmed/erased in a shorter time period. FIG. 7 is a graph of the predicted data storing time period of the memory device of Example 1. As illustrated in FIG. 7, at the same programming speed and erasing speed, at the same voltage, and with the memory device under the same conditions as in FIG. 6, where a programming voltage of about 5 V and an erasing voltage of about −1 V were applied and the programming speed and the erasing speed was about 1 msec, the difference between the flat band voltages was still maintained at about 4V after about 10 years, which means that the memory storing characteristics of the memory device may be improved.

These improved characteristics of the memory device may be due to the uniform monolayer arrangement of nanocrystals and may satisfy the characteristics required to manufacture a gigabyte memory device. The memory device according to example embodiments may include a polyelectrolyte film on the tunneling oxide layer, which enables uniform monolayer arrangement of nanocrystals due to electrostatic attraction. The device characteristics may be controlled and a memory device with improved device characteristics may be provided.

While example embodiments have been particularly shown and described with reference to example embodiments thereof, it will be understood by those of ordinary skill in the art that various changes in form and details may be made therein without departing from the spirit and scope of the following claims.

What is claimed is:

1. A method of manufacturing a memory device, the method comprising:
providing a substrate;
forming at least one tunneling oxide layer on a surface of the substrate;
forming a polyelectrolyte layer on a surface of the tunneling oxide layer;
forming a monolayer of nanocrystals on the polyelectrolyte layer; and
forming a control oxide layer on the surface of the tunneling oxide layer in which the nanocrystals are arranged.

2. The method of claim 1, further comprising:
forming a source and drain region on the surface of the substrate; and
forming a control gate on the surface of the control oxide layer.

3. The method of claim 1, wherein the at least one tunneling oxide layer Includes first and second tunneling oxide layers.

4. The method of claim 1, wherein the polyelectrolyte forming the polyelectrolyte layer includes at least one polymer selected from the group consisting of polyallylamine hydrochloride, polydiallyldimethylammonium chloride, polyacrylic acid, poly sodium-4-styrene-sulfonate, polyethyleneimine and polyvinyl pyridine.

5. The method of claim 1, wherein the material forming the at least one tunneling oxide layer is at least one selected from the group consisting of silicon oxide, silicon nitride, lanthanum oxide, lanthanum silicate and lanthanum aluminate.

6. The method of claim 1, wherein the material forming the at least one tunneling oxide layer is at least one selected from the group consisting of SiO₂, SiOₓN_{y}, ZrO₂, HfONₓ, ZrONₓ, TiO₂, Ta₂O₅, La₂O₃, PrO₂, HfSiO₂, ZrSiO₂ and HfSiOₓN_{y}.

7. The method of claim 1, wherein the nanocrystals are arrayed on the polyelectrolyte layer using a method selected from the group of methods consisting of spin-coating, dip coating, and drop casting.

8. The method of claim 1, wherein the nanocrystals are capped with polar organic molecules having charges.

9. The method of claim 1, wherein the nanocrystals are at least one kind selected from the group consisting of metal nano particles including Pt, Pd, Co, Cu, Mo, Ni, Fe; Group II-VI compound semiconductor nano particles including CdS, CdSe, CdTe, ZnS, ZnSe, ZnTe, HgS, HgSe, HgTe; Group III-V compound semiconductor nano particles including GaN, GaP, GaAs, InP, InAs; and PbS, PbSe, and PbTe,
wherein the nanocrystals are a metal or alloy having a size of about 10 nm or less or are in a Core-Shell structure.

10. The method of claim 1, wherein the nanocrystals are arranged as a monolayer.

11. A memory device comprising:
a substrate;
a source region and a drain region that are formed in the substrate and are spaced apart from each other;
a memory cell that is formed on the surface of the substrate, connecting the source region and the drain region, and including a plurality of nanocrystals, wherein the memory cell includes at least one tunneling oxide layer formed on the substrate and a control oxide layer including a plurality of nanocrystals formed on the at least one tunneling oxide layer; and
a control gate formed on the memory cell.

12. The memory device of claim 11, wherein the at least one tunneling oxide layer includes first and second tunneling oxide layers.

13. The memory device of claim 11, wherein the material forming the at least one tunneling oxide layer is at least one selected from the group consisting of silicon oxide, silicon nitride, lanthanum oxide, lanthanum silicate, and lanthanum aluminate.

14. The memory device of claim 11, wherein the material forming the at least one tunneling oxide layer is at least one selected from the group consisting of SiO₂, SiOₓN_{y}, ZrO₂, HfONₓ, ZrONₓ, TiO₂, Ta₂O₅, La₂O₃, PrO₂, HfSiO₂, ZrSiO₂, and HfSiOₓN_{y}.

15. The memory device of claim 11, wherein the nanocrystals are at least one kind selected from the group consisting of metal nano particles including one kind of nanocrystals selected from the group consisting of metal nano particles including Pt, Pd, Co, Cu, Mo, Ni, Fe; Group II-VI compound semiconductor nano particles including CdS, CdSe, CdTe, ZnS, ZnSe, ZnTe, HgS, HgSe, HgTe; Group III-V group compound semiconductor nano particles including GaN, GaP, GaAs, InP, InAs; and PbS, PbSe, and PbTe,
wherein the nanocrystals are a metal or alloy having a size of about 10 nm or less or are in a Core-Shell structure.

16. The memory device of claim 11, wherein a plurality of nanocrystals included in the control oxide layer are arrayed as a monolayer.

17. A method of operating a memory device, the method comprising:
grounding a source region; and
applying a voltage (Vd>0) to a drain region so that electrons move from the source region to the drain region, and wherein when a gate voltage Va is greater than a drain voltage Vd, electrons move to a memory cell.

18. The method of claim 17, wherein the gate voltage is a write voltage (Va=0).

19. The method of claim 17, further comprising:
applying a read voltage smaller that the gate voltage Va during writing to the drain region, wherein the gate voltage is about 0.

20. The method of claim 17, further comprising:
applying an erase voltage to the source region to allow electrons to move to the source region, wherein the gate voltage is about 0 and the erase voltage is greater than 0.
